(19) United States
(12) Patent Application Publication
(10) Pub. No.: US 2014/0264731 A1
(43) Pub. Date: Sep. 18, 2014

(54) PROGRAMMABLE E-FUSE FOR AN INTEGRATED CIRCUIT PRODUCT

(71) Applicant: GLOBALFOUNDRIES INC., Grand Cayman (KY)

(72) Inventors: Andrew Kim, Poughkeepsie, NY (US); O Sung Kwon, Wappingers Falls, NY (US); Xiaoqiang Zhang, Rexford, NY (US); Seung-Hyun Rhee, Fishkill, NY (US); Anurag Mittal, Wappingers Falls, NY (US)

(73) Assignee: GLOBALFOUNDRIES INC., Grand Cayman (KY)

(21) Appl. No.: 13/833,934

(22) Filed: Mar. 15, 2013

(51) Int. Cl. H01L 23/525; H01L 23/34

(52) U.S. Cl. CPC H01L 23/5256; H01L 23/34
USPC 257/529

(57) ABSTRACT

One illustrative e-fuse device disclosed herein includes first and second conductive structures, a first electrically conductive heat cage element that is conductively coupled to the first conductive structure, wherein the first heat cage element is adapted to carry an electrical current, a second electrically conductive heat cage element that is conductively coupled to the second conductive structure, wherein the second heat cage element is adapted to carry the electrical current, and a programmable, electrically conductive e-fuse element that is conductively coupled to each of the first and second electrically conductive heat cage elements and adapted to carry the electrical current, wherein the e-fuse element is positioned adjacent to each of the first and second electrically conductive heat cage elements.

### BACKGROUND OF THE INVENTION

1. Field of the Invention

Generally, the present disclosure relates to the manufacture of FET semiconductor devices, and, more specifically, to various embodiments of a programmable e-fuse for use on integrated circuit products.

2. Description of the Related Art

In modern integrated circuits, a very high number of individual circuit elements, such as field effect transistors in the form of CMOS, NMOS, PMOS elements, resistors, capacitors and the like, are formed on a single chip area. Typically, feature sizes of these circuit elements are decreased with the introduction of every new circuit generation, to provide currently available integrated circuits with an improved degree of performance in terms of speed and/or power consumption. In addition to the large number of transistor elements, a plurality of passive circuit elements, such as capacitors, resistors and the like, are typically formed in integrated circuits that are used for a plurality of purposes, such as for decoupling.

Due to the reduced dimensions of circuit elements, not only the performance of the individual transistor elements may be increased, but also their packing density may be improved, thereby providing the potential for incorporating increased functionality into a given chip area. For this reason, highly complex circuits have been developed which may include different types of circuits, such as analog circuits, digital circuits and the like, thereby providing entire systems on a single chip (SoC). Furthermore, in sophisticated micro-controller devices, an increasing amount of storage capacity may be provided on a chip with the CPU core, thereby also significantly enhancing the overall performance of modern computer devices.

For a variety of reasons, the various circuit portions may have significantly different performance capabilities, for instance with respect to useful lifetime, reliability and the like. For example, the operating speed of a digital circuit portion, such as a CPU core and the like, may depend on the configuration of the individual transistor elements and also on the characteristics and performance of the metallization system coupled to the CPU core. Consequently, the combination of the various circuit portions in a single semiconductor device may result in a significantly different behavior with respect to performance and reliability. Variations in the overall manufacturing process flow may also contribute to further variations in the performance capabilities between various circuit portions. For these reasons, in complex integrated circuits, frequently, additional mechanisms are used so as to allow the circuit itself to adapt or change the performance of certain circuit portions to comply with the performance characteristics of other circuit portions. Such mechanisms are typically used after completing the manufacturing process and/or during use of the semiconductor device. For example, when certain critical circuit portions no longer comply with corresponding device performance criteria, adjustments may be made, such as re-adjusting an internal voltage supply, re-adjusting the overall circuit speed and the like, to correct such underperformance.

In computing, e-fuses are used as a means to allow for the dynamic real-time reprogramming of computer chips. Speaking abstractly, computer logic is generally “etched” or “hard-coded” onto a silicon chip and cannot be changed after the chip has been manufactured. By utilizing an e-fuse, or a number of individual e-fuses, a chip manufacturer can change some aspects of the circuits on a chip. If a certain sub-system fails, or is taking too long to respond, or is consuming too much power, the chip can instantly change its behavior by blowing an e-fuse. Programming of an e-fuse is typically accomplished by forcing a large electrical current through the e-fuse. This high current is intended to break the e-fuse structure, which results in an “open” electrical path. In some applications, lasers are used to blow effuses. Fuses are frequently used in integrated circuits to program redundant elements or to replace identical defective elements. Further, fuses can be used to store die identification or other such information, or to adjust the speed of a circuit by adjusting the resistance of the current path. Device manufacturers are under constant pressure to produce integrated circuit products with increased performance and lower power consumption relative to previous device generations. This drive applies to the manufacture and use of e-fuses as well.

Prior art e-fuses come in various configurations. FIGS. 1A-1C depict illustrative examples of some forms of prior art e-fuses. FIG. 1A is a plan view of a very simple e-fuse 10 comprised of conductive lines or structures 12 having a reduced-size metal line 14 coupled to the conductive structures 12. The e-fuse 10 may sometime be referred to as a “BEOL” type e-fuse as it is typically made using the materials used in forming various metallization layers in so-called Back-End-Of-Line activities.

FIG. 1B is a cross-sectional view of another type of e-fuse 15 that extends between two illustrative metal layers, M2 and M3, formed on an integrated circuit product. In general, the e-fuse 15 is comprised of schematically depicted conductive lines 16, 18 that are formed in the metallization layers M2, M3, respectively. A reduced-size metal structure or via 20 is conductively coupled to the conductive lines 16, 18. The e-fuse 15 may sometimes be referred to as an “I” type e-fuse due to its cross-sectional configuration.

FIG. 1C is a plan view of yet another illustrative example of an e-fuse 21. In this example, the e-fuse 21 is comprised of conductive lines or structures 22 having a reduced-size metal line 24 that is conductively coupled to the conductive structures 22. In this example, a plurality of non-conductive “dummy” lines 26 are formed adjacent to the metal line 24. Such dummy lines 26 are typically formed to facilitate more accurate patterning.

All of the e-fuses depicted in FIGS. 1A-1C work by passing a sufficient current though the e-fuse such that, due to resistance heating, the reduced-size metal line (14, 20, 24) will eventually rupture, thereby creating an open electrical circuit. However, these types of e-fuses require a relatively high programming current, e.g., about 35 mA or higher. Such a high programming current is generally not desirable for e-fuses, as such a high programming current will require a relatively larger programming transistor, which means increased consumption of valuable space on the chip. Moreover, a higher programming current degrades the sensing margin for sensing circuits that are used to determine whether or not the e-fuse is programmed, i.e., blown.

The present disclosure is directed to various embodiments of a programmable e-fuse for use on integrated circuit products that may solve or reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various embodiments of a programmable e-fuse for use on integrated circuit products. One illustrative e-fuse device disclosed herein includes first and second conductive structures, a first electrically conductive heat cage element that is conductively coupled to the first conductive structure, wherein the first heat cage element is adapted to carry an electrical current, a second electrically conductive heat cage element that is conductively coupled to the second conductive structure, wherein the second heat cage element is adapted to carry the electrical current, and a programmable, electrically conductive e-fuse element that is conductively coupled to each of the first and second electrically conductive heat cage elements and adapted to carry the electrical current, wherein the e-fuse element is positioned adjacent to each of the first and second electrically conductive heat cage elements.

Another illustrative e-fuse device disclosed herein includes first and second conductive structures and a conductive serpentine-shaped structure that comprises a programmable, electrically conductive e-fuse element. A first conductive leg of the serpentine structure is conductively coupled to the first conductive structure and a second conductive leg of the serpentine structure is conductively coupled to the second conductive structure, wherein at least a portion of the e-fuse element is positioned between at least a portion of the first and second conductive legs.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict various illustrative examples of prior art e-fuse devices; and

FIGS. 2A-2C depict various illustrative embodiments of a novel programmable e-fuse disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various embodiments of a programmable e-fuse for use on integrated circuit products. As will be readily apparent to those skilled in the art upon a complete reading of the present application, the various embodiments of the novel e-fuses disclosed herein may be employed on any type of integrated circuit product, including, but not limited to, logic devices, memory devices, etc. With reference to the attached figures, various illustrative embodiments of the novel e-fuse structures disclosed herein will now be described in more detail.

FIGS. 2A-2C depict illustrative examples of the novel e-fuse 100 disclosed herein. FIG. 2A is a plan view of an illustrative e-fuse 100 that may be formed in a single metallization layer of an integrated circuit product. In general, the e-fuse 100 is positioned between two illustrative conductive lines or structures 102A, 102B, and the actual e-fuse element 106, i.e., the portion of the e-fuse 100 that will actually rupture when properly programmed, is positioned adjacent to, or interleaved within, two illustrative electrically conductive heat cage elements or legs 108A, 108B. In one illustrative embodiment, the e-fuse element 106 may be designed such that the e-fuse element 106, when subject to the proper programming current, will actually rupture near the midpoint 106R of the e-fuse element 106, although it may rupture at another location along the e-fuse element 106. The heat cage elements or legs 108A, 108B are each conductively coupled to one of the conductive structures 102A, 102B and current passes through the heat cage elements 108A, 108B during operation.

In one embodiment, the e-fuse 100 disclosed herein has a generally serpentine-shaped configuration or “Z” shaped configuration as depicted in the drawings. In such a configuration, one end of the serpentine-shaped structure is conductively coupled to the first conductive structure 102A and the other end of the serpentine structure is conductively coupled to the second conductive structure 102B. Stated another way, a first conductive leg 108A of the serpentine structure is conductively coupled to the first conductive structure 102A and a second conductive leg 108B of the serpentine structure is conductively coupled to the second conductive structure 102B, wherein at least a portion of the e-fuse element 106 is positioned between at least a portion of the first and second conductive legs 108A, 108B.

The physical size, i.e., the cross-sectional area, of the heat cage elements 108A, 108B and the e-fuse element 106 may be the same or they may be different. In some embodiments, the cross-sectional area of the e-fuse element 106 may be less than the cross-sectional area of the heat cage elements 108A, 108B. In some embodiments, the heat cage elements 108A, 108B and the e-fuse element 106 are all positioned, at least partially, in the same plane, e.g., a substantially horizontal or vertical plane. Stated another way, in one embodiment, the conductive serpentine-shaped structure may all be positioned in the same plane. In some embodiments, the first heat cage element 108A, the second heat cage element 108B and the programmable, electrically conductive e-fuse element 106 are all a part of a single continuous conductive line structure. In another embodiment, the first heat cage element 108A, the second heat cage element 108B and the programmable, electrically conductive e-fuse element 106 are separate line-type structures that are conductively coupled together by other line-type structures.

In terms of design, the physical size of the e-fuse element 106 and heat cage elements 108A, 108B may vary depending upon the particular application. The axial length 107 of the e-fuse 100 may also vary depending upon the particular application. In general, the components of the e-fuse 100 may be made of any conductive material, e.g., a metal, polysilicon, and it may or may not have a metal silicide layer as part of the materials of construction. The e-fuse 100 may be manufactured using traditional manufacturing techniques, depending upon the materials of construction, e.g., damascene techniques, deposition/etch techniques, etc.

In operation, a programming current is passed through the e-fuse 100 until such time as a portion of the e-fuse element 106 ruptures due to resistance heating. However, unlike prior art e-fuse structures, due to the presence of the heat cage elements or legs 108A, 108B, the programming current for the novel e-fuse 100 disclosed herein is significantly lower than that of the prior art e-fuse devices wherein the actual fuse element is not positioned adjacent to any structures similar to the heat cage elements 108A, 108B. During operation, the heat cage elements 108A, 108B also conduct current and heat up due to resistance heating.

However, due to the presence of other surrounding, non-conducting materials, such as surrounding insulation materials (not shown), the heat generated in the heat cage elements 108A, 108B dissipates, to at least some degree, outwardly away from the heat cage elements 108A, 108B, as indicated by the arrows 109, thereby decreasing the temperature, to some degree, of the heat cage elements 108A, 108B. However, since the e-fuse element 106 is positioned adjacent to the heated heat cage elements 108A, 108B, the temperature of the e-fuse element 106 cannot dissipate heat as rapidly as does the heat cage elements 108A, 108B. Simply put, the heated heat cage elements 108A, 108B reduce the amount of heat lost from the e-fuse element 106 as it is heated during programming operations. Thus, the temperature of the e-fuse element 106 will be greater than that of the heat cage elements 108A, 108B. Accordingly, as current flows through the e-fuse 100, the e-fuse element 106 will eventually reach a temperature at which time it will rupture, as intended, and this rupturing will occur prior to the heat cage elements 108A, 108B rupturing. To take advantage of the heating effect of the heat cage elements 108A, 108B, they should be placed in relative close proximity to the e-fuse element 106. In one illustrative example where the e-fuse element 106 has a width 106W, the spacing 110 between the e-fuse element 106 and the heat cage elements 108A, 108B may be on the order of about 2-3 times the width 106W, although such spacing may vary depending upon the particular application.

As will be recognized by those skilled in the art after a complete reading of the present application, the novel e-fuse 100 disclosed herein may be implemented in a vast variety of configurations. Moreover, the novel e-fuse 100 may be employed at any metallization level and at any location within an integrated circuit product. To that end, FIG. 2B depicts an illustrative example wherein the novel e-fuse 100 extends between two illustrative metal layers, M2 and M3, formed on an integrated circuit product. In this embodiment, the e-fuse 100 may be manufactured at the same time as various so-called via structures are formed between the metallization layers M2, M3. To that end, FIG. 2B depicts the illustrative example wherein via elements 109A-C are part of the heat cage element 108A, the e-fuse element 106 and the heat cage element 108B, respectively.

FIG. 2C is a plan view of yet another illustrative example of the novel e-fuse 100 disclosed herein. In this example, as before, the e-fuse 100 is positioned between two illustrative conductive lines or structures 102A, 102B, and at least a portion of the e-fuse element 106 is positioned between the adjacent the heat cage elements 108A, 108B. The heat cage elements 108A, 108B are each conductively coupled to the conductive structures 102A, 102B, respectively, and current passes through the heat cage elements 108A, 108B during programming operations. In this illustrative example, a plurality of non-conductive “dummy” lines 112 are formed adjacent to the heat cage elements 108A, 108B, however, the e-fuse element 106 disclosed herein may be employed with or without the formation of such dummy lines, depending upon the particular application.

The novel e-fuse 100 disclosed herein provides significant advantages relative to prior art e-fuse designs. A computer simulation was conducted to compare the performance of the prior art e-fuse 21 depicted in FIG. 1C to that of the novel e-fuse 100 depicted in FIG. 2C. In the prior art design, a programming current of about 40 mA was required to rupture the e-fuse 21. In contrast, the novel e-fuse 100 shown in FIG. 2C only required a programming current of about 27 mA to rupture the e-fuse element 106. Thus, the novel e-fuse 100 may be ruptured using a programming current that is about 67% (27/40) of the programming current used to rupture the prior art e-fuse 21 depicted in FIG. 1C. Such a significant reduction in programming current is very beneficial to device manufacturers. More specifically, a lower programming current for the e-fuse 100 means that a relatively smaller programming transistor may be used, which means less consumption of valuable space on the chip. Additionally, by using a lower programming current for the e-fuse 100, the sensing margin for sensing circuits that are used to determine whether or not the e-fuse 100 is programmed, i.e., blown, is increased.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An e-fuse device, comprising:
first and second conductive structures;
a first electrically conductive heat cage element that is conductively coupled to said first conductive structure, wherein said first heat cage element is adapted to carry an electrical current;
a second electrically conductive heat cage element that is conductively coupled to said second conductive structure, wherein said second heat cage element is adapted to carry said electrical current; and
a programmable, electrically conductive e-fuse element that is conductively coupled to each of said first and second electrically conductive heat cage elements and adapted to carry said electrical current, wherein said e-fuse element is positioned adjacent to each of said first and second electrically conductive heat cage elements.

2. The device of claim 1, wherein said first electrically conductive heat cage element, said second electrically conductive heat cage element and said programmable, electrically conductive e-fuse element are all a part of a single continuous conductive line structure.

3. The device of claim 1, wherein said first electrically conductive heat cage element, said second electrically conductive heat cage element and said programmable, electrically conductive e-fuse element are each separate conductive line structures and said first electrically conductive heat cage element is conductively coupled to said programmable, electrically conductive e-fuse element and said programmable, electrically conductive e-fuse element is conductively coupled to said second electrically conductive heat cage element.

4. The device of claim 1, wherein at least portions of said first electrically conductive heat cage element, said second electrically conductive heat cage element and said programmable, electrically conductive e-fuse element are all positioned in a single plane.

5. The device of claim 4, wherein said single plane is one of a substantially vertical plane or a substantially horizontal plane.

6. The device of claim 1, wherein said first and second conductive structures are conductive line structures.

7. The device of claim 6, wherein said first and second conductive structures are positioned in a common metallization layer of an integrated circuit product.

8. The device of claim 6, wherein said first and second conductive structures are positioned in different metallization layers of an integrated circuit product.

9. The device of claim 7, wherein said first electrically conductive heat cage element, said second electrically conductive heat cage element and said programmable, electrically conductive e-fuse element are all positioned in said common metallization layer.

10. The device of claim 8, wherein said first electrically conductive heat cage element, said second electrically conductive heat cage element and said programmable, electrically conductive e-fuse element extend between said different metallization layers.

11. The device of claim 1, wherein said first electrically conductive heat cage element, said second electrically conductive heat cage element and said programmable, electrically conductive e-fuse element define a serpentine-shaped structure, one end of which is conductively coupled to said first conductive structure and the other end of which is conductively coupled to said second conductive structure.

12. The device of claim 1, wherein said first electrically conductive heat cage element, said second electrically conductive heat cage element and said programmable, electrically conductive e-fuse element are comprised of a metal or polysilicon.

13. An e-fuse device, comprising:
first and second conductive structures; and
a conductive serpentine-shaped structure that comprises a programmable, electrically conductive e-fuse element, a first conductive leg of said serpentine-shaped structure being conductively coupled to said first conductive structure and a second conductive leg of said serpentine-shaped structure being conductively coupled to said second conductive structure, wherein at least a portion of said e-fuse element is positioned between at least a portion of said first and second conductive legs.

14. The device of claim 13, wherein said conductive serpentine-shaped structure is a single continuous conductive line structure.

15. The device of claim 13, wherein said first conductive leg of said serpentine-shaped structure, said second conductive leg of said serpentine-shaped structure and said programmable, electrically conductive e-fuse element are each separate conductive line structures and said first conductive leg of said serpentine-shaped structure is conductively coupled to said programmable, electrically conductive e-fuse element and said programmable, electrically conductive e-fuse element is conductively coupled to said second conductive leg of said serpentine-shaped structure.

16. The device of claim 13, wherein conductive serpentine-shaped structure is positioned in a single plane.

17. The device of claim 16, wherein said single plane is one of a substantially vertical plane or a substantially horizontal plane.

18. The device of claim 13, wherein said first and second conductive structures are conductive line structures.

19. The device of claim 13, wherein said first and second conductive structures are positioned in a common metallization layer of an integrated circuit product.

20. The device of claim 13, wherein said first and second conductive structures are positioned in different metallization layers of an integrated circuit product.

21. The device of claim 19, wherein said conductive serpentine-shaped structure is positioned in said common metallization layer.

22. The device of claim 20, wherein said conductive serpentine-shaped structure extends between said different metallization layers.
